(19) United States
(12) Patent Application Publication
(10) Pub. No.: US 2024/0388063 A1
(43) Pub. Date: Nov. 21, 2024

(54) SYSTEMS AND METHODS TO FILTER OPTICAL WAVELENGTHS

(71) Applicants: HUAWEI TECHNOLOGIES CANADA CO., LTD., Kanata (CA); McMaster University, Hamilton (CA)

(72) Inventors: Xun LI, Hamilton (CA); Chuanning NIU, Hamilton (CA); Sangzhi ZHAO, Hamilton (CA); Tan Huy HO, Kanata (CA)

(73) Assignees: HUAWEI TECHNOLOGIES CANADA CO., LTD., Kanata (CA); McMaster University, Hamilton (CA)

(21) Appl. No.: 18/785,715

(22) Filed: Jul. 26, 2024

Related U.S. Application Data
(63) Continuation of application No. PCT/CA2022/050144, filed on Feb. 1, 2022.

(51) Int. Cl. H01S 5/183; G02B 5/18; H01S 5/062

(52) U.S. Cl. CPC H01S 5/18361; G02B 5/1857; H01S 5/06246

(57) ABSTRACT

An optical grating comprising a refractive index with a periodic pattern that includes a base period Λ₀; a periodic sampling of the base period, with a first period Λ₁ and a first duty cycle p₁, thereby defining a single-sampled grating (SSG); and a periodic sampling of the SSG, with a second period Λ₂ and a second duty cycle p₂. The resulting dual-sampled grating (DSG) can have a reflection spectrum containing reflection peaks. If two DSGs having different reflection spectra share a common interface, a tunable optical filter can be produced, where electrical or heating means can cause a reflection peak of one spectrum to be shifted to coincide with a reflection peak of the other spectrum, thereby filtering the corresponding wavelength. By inserting between the two DSGs a gain medium and a phase-tuning medium, a laser source structure is realized. Either device can be produced by etching or stacking methods.

### CROSS-REFERENCE TO RELATED APPLICATION

This application is a continuation of International Application No. PCT/CA2022/050144, entitled “SYSTEMS AND METHODS TO FILTER OPTICAL WAVELENGTHS”, filed on Feb. 1, 2022, the entire contents of which are hereby incorporated by reference.

### TECHNICAL FIELD

This invention pertains generally to the field of optical devices and in particular, to systems and methods to filter optical wavelengths. Particular embodiments are directed to wavelength-tunable filters and wideband, wavelength tunable lasers.

### BACKGROUND

Wavelength tunable lasers, where a lasing wavelength can readily be selected over a certain range, can be very useful in many applications and in some cases essential, such as in wavelength division multiplexing (WDM) systems and wavelength routing networks. As light sources in optical communication systems and networks, wavelength tunable lasers also need to be modulated. Direct modulation is the most cost-effective and reliable solution. Driven by applications with cost-effectiveness as a primary objective, typical requirements of wavelength tunable lasers include a wide tuning range, and the ability for their intensity to be modulated directly.

Available wideband wavelength tunable lasers typically have a long laser cavity and because of this, their intensity cannot be directly modulated at high-speed (i.e. high modulation rate). As for distributed feedback (DFB) lasers, and distributed Bragg reflector (DBR) wavelength tunable lasers, these wavelength tunable lasers have a normal length laser cavity and they typically have a limited tuning range. Thus, to support a wide tuning range (e.g. full C-band), an array of wavelength tunable lasers is needed.

When an array of wavelength tunable lasers (“wavelength tunable laser array”) is used as one tunable laser source, the array of wavelength tunable lasers can be modulated directly. However, an extra beam combiner or an extra WDM typically has to be integrated with the tunable laser array, in order to collect light from the many different output ports, and an extra semiconductor optical amplifier is often required to compensate for losses introduced by the combiner or WDM. The fabrication of such a wavelength tunable laser array is complex and is usually not a cost-effective solution.

As an inherent semiconductor material property, the refractive index n of the mediums of a wavelength tunable laser can typically be changed within 1% (Δn/n≈1%), regardless of the tuning method (e.g., through electric field, or injection current, or temperature, etc.). Consequently, a wavelength tuning range is typically limited to 1% of the lasing wavelength of the wavelength tunable laser, i.e., ˜10 nm, which is insufficient in many applications.

For some applications, it also matters that modulation of the wavelength tunable laser can be done at a high speed (i.e. frequency or rate), and this can be facilitated when the laser cavity of the wavelength tunable laser is made shorter.

Therefore, there is a need for wavelength tuneable lasers that can obviate or mitigate one or more limitations of the prior art.

This background information is provided to reveal information believed by the applicant to be of possible relevance to the present invention. No admission is necessarily intended, nor should be construed, that any of the preceding information constitutes prior art against the present invention.

### SUMMARY

Embodiments of the present invention include an optical dual-sampled grating comprising a medium the refractive index of which having an overall periodicity that results from a base periodicity, a first periodicity that samples the base periodicity, and a second periodicity that samples the first periodicity. Each periodicity is a periodic pattern along the length of the grating that describes the variation of the grating's refractive index along the grating. A resulting grating has a reflection spectrum that depends on parameters of the sampling periodicities, i.e. the period and duty cycle of each periodicity. In some embodiments, the scope of possible filtering spectra can be increased even further by sampling a DSG to create a “triple-sampled grating” (TSG), by sampling a TSG to create a quadruple-sampled grating (QSG), and so on.

The reflection spectrum of a grating having a pattern that periodically samples the pattern of a single-sampled grating (SSG) can include the reflection peaks as would the SSG, as well as additional reflection peaks in between. This effectively causes a reflection spectrum with a free spectral range (FSR) that is shorter than that of the SSG. The FSR can be selected by properly choosing parameters of the first and second sampling periodicities, in particular the period and duty cycle of each periodicity. In an embodiment, the FSR can be proportional to the difference between the first sampling period and the second sampling period.

The FSR is a length in the frequency domain and to obtain a dual-sampled grating (DSG) having the same FSR as a reference SSG, the sampling periods of a DSG can be shorter than the sampling period of the reference SSG. Because of that, the physical length of a DSG can be made shorter than the physical length of the reference SSG having the same FSR.

When used by itself, a DSG according to embodiments can be a filter that filters optical wavelengths into particular reflection spectra, and if two DSGs are interfaced and used as one filter, the one filter can have a tunable reflection and/or transmission spectrum. In such a case, a Vernier effect can be realized between the two reflection spectra of the DSGs, by shifting a reflection peak of the first DSG to align with a reflection peak of the second DSG. In embodiments, shifting reflection peaks of the DSGs can be caused by tuning the temperature of each DSG; or by applying a forward bias and tuning a current to introduce a carrier flow through the materials of the DSGs; or by applying a reverse bias and tuning a voltage to introduce an electrostatic field on the materials of the DSGs; or by applying a mechanical force to the materials of the DSGs

In an embodiment, two DSGs can be used as the two reflectors (i.e. mirrors) bounding a laser cavity and because for a desired FSR, each DSG can be made shorter than a SSG, a laser cavity in which a DSG is used for each of the two reflector (i.e. mirror) can also be made shorter.

If the FSR of each of two DSGs acting as reflectors (i.e. mirrors) are slightly different, the wavelength at the point of overlap can resonate as the lasing wavelength in the laser cavity. A laser source according to embodiments can therefore include a laser cavity comprising a first DSG as a first mirror, a gain medium, a phase tuning medium to obtain phase matching conditions with the laser cavity, and a second DSG as a second mirror. A lasing wavelength can be one of the many wavelengths achievable by tuning a temperature, current or voltage at each of the first DSG and the second DSG. Lasing resonance (i.e. constructive interference of subsequent optical waves with prior optical waves) can be achieved by tuning a current at the phase tuning medium, and amplitude (i.e. population inversion) can be achieved by tuning a current at the gain medium. By making one of the two DSGs partially transparent, the lasing wavelength can be emitted from the laser source.

A laser cavity using DSGs as bounding mirrors, according to embodiments, can be made shorter than a laser cavity using Bragg gratings or SSGs as bounding mirrors and by being shorter, a higher speed, direct modulation of the laser cavity can be achieved. When DSGs are used as opposing mirrors of a laser cavity, the laser cavity can be made shorter and the DSGs can also be used for tuning of the lasing wavelength resonating in the laser cavity via a Vernier effect between their reflection peaks. By tuning the effective refractive indices of the two DSGs independently, different pairs of reflection peaks can be made to overlap and therefore resonate in the laser cavity. A wavelength-tunable laser source having a laser cavity using DSGs as mirrors can be directly modulated at higher speed (frequency) than prior art wavelength-tunable laser sources.

Embodiments include an optical device comprising a grating medium having a periodic refractive index the periodicity of which includes a base period Λ₀, a first period Λ₁, and a second period Λ₂; such that a reflection spectrum of the grating medium includes a plurality of reflection peaks.

In embodiments, the periodic refractive index of a grating medium can further comprise a duty cycle associated with the first period Λ₁, and a duty cycle associated with the second period Λ₂, wherein first period Λ₁ is different from the second period Λ₂.

In embodiments, for a given separation between adjacent reflection peaks, the separation referred to as the reflection spectrum's free spectral range (FSR), the length of DSG can be shorter than the length of a SSG.

In embodiment, the FSR of a DSG can be substantially proportional to the difference between the first period Λ₁ and the second period Λ₂; and inversely proportional to the product between the first period Λ₁ and the second period Λ₂.

In embodiments, the periodic refractive index of a grating medium can further comprise one or more additional periods and one or more additional duty cycles. In other words, embodiments include not only a DSG and devices that include at least one DSG, but also a TSG, a QSG and so on, as well as devices that include at least one TSG, devices that include at least one QSG, and so on.

In embodiments, a grating medium such as a DSG can include a first material having a first refractive index, and a second material having a second refractive index.

In embodiments, an optical device can further include, interfaced with a first grating medium, a second grating medium having a second periodic refractive index, the periodicity of which has second parameters including: a base period Λ₀′, a first period Λ₁′, a first duty cycle p₁′, a second period Λ₂′, and a second duty cycle p₂′; wherein the second parameters are selected such that a reflection spectrum of the second grating medium includes a plurality of reflection peaks.

In embodiments, the periodic refractive index of at least one grating medium can be operative to be tuned such that a reflection peak of a first grating medium is shifted to coincide with a reflection peak of a second grating medium.

In embodiments, an optical device can include, interfaced between a first grating medium and a second grating medium, a phase tuning medium having a refractive index the tuning of which can cause the phase of optical waves propagated within to be shifted; and a gain medium, the tuning of which can cause the amplitude of optical waves propagated within to be modulated.

In embodiments, tuning of the refractive index of one or more mediums can be performed with current injection.

In embodiments, tuning of the refractive index of one or more mediums can be performed by tuning the medium's temperature.

In embodiments, tuning of the refractive index of one or more mediums can be performed by applying an external electric field to the medium.

In embodiments, tuning of the refractive index of one or more mediums can be performed by applying mechanical force to the medium.

In embodiments, tuning of a gain medium can be performed with current injection.

In embodiments, a medium can be a stack of films, deposited on a substrate, and can further include films to improve electrical connections.

In embodiments, one or more mediums can be electrically doped.

Embodiments include methods of filtering at least one wavelength from an optical beam, comprising: applying to a base grating medium having a periodic refractive index the period of which is Λ₀, a first period Λ₁ and a second period Λ₂; such that a reflection spectrum of the resulting grating includes a plurality of reflection peaks.

In embodiments, a method can further include a periodic refractive index having a duty cycle associated with the first period Λ₁, and a duty cycle associated with the second period Λ₂, wherein first period Λ₁ is different from the second period Λ₂.

In embodiments, for a given separation between adjacent reflection peaks, the separation referred to as the reflection spectrum's free spectral range (FSR), the length of the grating medium can be made shorter than the length of another grating medium having a single first period.

In embodiments the FSR between adjacent reflection peaks of a grating medium having a periodic refractive index can be substantially proportional to the difference between the first period Λ₁ and the second period Λ₂; and inversely proportional to the product between the first period Λ₁ and the second period Λ₂.

In embodiments, a method of filtering at least one wavelength can include a grating medium having one or more additional periods and one or more additional duty cycles.

In embodiments, a method can include the grating medium having a first material having a first refractive index, and a second material having a second refractive index.

In embodiments, a method can further include interfacing to a first grating medium, a second grating medium having a second periodic refractive index, the periodicity of which has second parameters including: a base period Λ₀′, a first period Λ₁′, a first duty cycle p₁′, a second period Λ₂′, and a second duty cycle p₂′; wherein the second parameters are selected such that a reflection spectrum of the second grating medium includes a plurality of reflection peaks.

In embodiments, a method can further include tuning the periodic refractive index of at least one grating medium such that one reflection peak of the first grating medium is shifted to coincide with one reflection peak of the second grating medium.

In embodiments, a method can further include interfacing between a first grating medium and a second grating medium, a phase tuning medium having a refractive index the tuning of which causes the phase of optical waves propagated within to be shifted; and a gain medium, the tuning of which causes the amplitude of optical waves propagated within to tuned.

In embodiments, tuning the refractive index of one or more mediums can be performed with current injection.

In embodiments, tuning the refractive index of one or more mediums can be performed by tuning the medium's temperature.

In embodiments, tuning the refractive index of one or more mediums can be performed by applying an external electric field to the medium.

In embodiments, tuning the refractive index of one or more mediums can be performed by applying mechanical force to the medium.

In embodiments, tuning a gain medium can be performed by current injection.

### BRIEF DESCRIPTION OF THE DRAWINGS

FIG. 1 illustrates the parameters used to describe the periodicity of a DSG, according to embodiments.

FIG. 2 illustrates physical gratings manufactured from inscribing the patterns of FIG. 1 onto physical materials, according to embodiments of the present disclosure.

FIG. 3 illustrates a tunable optical filter according to an embodiment of the present disclosure.

FIG. 4 illustrates a wideband wavelength tunable directly modulated laser (DML) source, with dual-sampled gratings as mirrors, according to embodiments.

FIG. 5 illustrates a cross-section of a vertical-cavity surface-emitting laser (VCSEL) including a front DSG and a rear DSG, according to an embodiment.

FIG. 6a is graph showing a reflection spectrum of a simulated base Bragg grating.

FIG. 6b is a graph showing a reflection spectrum of a simulated single-sampled grating (SSG).

FIG. 6c is a graph showing a reflection spectrum of a simulated DSG of the present disclosure.

FIG. 7 shows two overlapping reflection spectra: one for a DSG with parameters that result in an FSR of 5 nm, and the other for a DSG with parameters that result in a FSR of 6 nm, according to simulated embodiments.

FIG. 8 includes a reflection spectrum for a simulated front DSG 420, and a reflection spectrum for a simulated rear DSG 425, according to an embodiment.

It will be noted that throughout the appended drawings, like features are identified by like reference numerals.

### DETAILED DESCRIPTION

Embodiments of the present disclosure include a dual-sampled grating (DSG), a wideband, wavelength-tunable optical filter comprising at least one DSG, and a wideband, wavelength-tunable, directly modulated laser source comprising two DSGs as mirrors. In a wideband, wavelength-tunable, directly modulated laser source, high-speed direct modulation is enabled by at least one of two DSGs. The DSG of the present disclosure is shorter than a single sampled grating (SSG) having the same free spectral range (FSR), thereby allowing the laser cavity of a wideband, wavelength-tunable, directly modulated laser to be shorter than a wideband, wavelength-tunable, directly modulated laser comprising conventional gratings (e.g. a Bragg grating or a single sampled grating (SSG) as mirrors), which in turn allows the wideband, wavelength-tunable, directly modulated laser to be modulated at a higher speed (i.e. higher frequency or higher rate).

In embodiments, a medium refers to a medium propagating a spectrum of optical waves, regardless of how many distinct materials, defects, impurities, dopants, films, and substructures it contains. As such, a medium can be a medium made of one or more materials, a gain medium, a phase tuning medium, or another optical wave-propagating medium used for another purpose. While a material can be characterized by a refractive index, a medium propagating an optical wave can be characterized by an “effective” refractive index that takes into account the different materials it may contains.

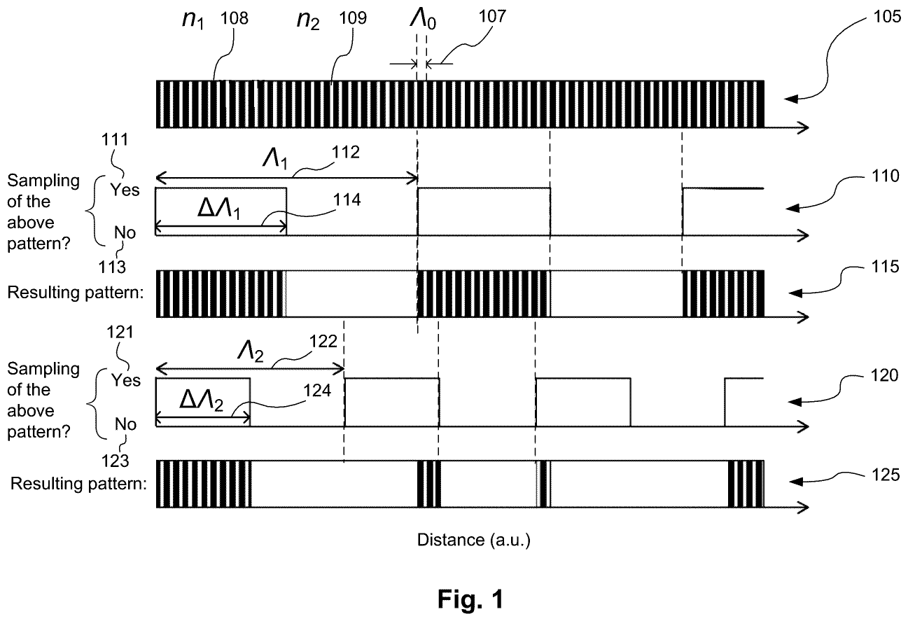

In an embodiment, a DSG is an optical grating comprising a spatially varying refractive index. The refractive index variation has a pattern along the optical grating, or more specifically a periodicity. The DSG pattern includes a periodic sampling of a first pattern, the first pattern itself periodically sampling a base periodic pattern. In other words, a DSG comprises a medium having a refractive index the variation of which includes a second sampling periodicity, of a first sampling periodicity, of a base period. Each periodicity can be described with a respective spatial period and a respective spatial duty cycle, which will be defined in FIG. 1.

A DSG according to embodiments is a medium having a periodic refractive index. The DSG's periodicity can be described as the result of a base grating that is sampled with a first spatial period and with a second spatial period. In other words, whereas a periodic sampling of a base Bragg grating would result in a SSG, a periodic sampling of that resulting SSG would result in a DSG according to embodiments. In general, the second period is different than the first period. The resulting grating has a periodicity that includes the first period and the second period. Compared to a SSG that is formed by sampling a base Bragg grating once, a DSG resulting from sampling a SSG (or sampling a Bragg grating twice) can have the same free spectral range (FSR) as a SSG, but with much-reduced sampling periods. Effectively, a sampling of a SSG can result in a grating with additional reflection peaks over the reflection spectrum of the SSG. In some applications, for the same FSR, a DSG can be shorter than a SSG.

In embodiments, a “periodicity” is a pattern with a spatial repetition along an axis. An overall periodicity can be the result of one or more constituent periodicities, each constituent periodicities having a period and a duty cycle. In embodiments, a “period” is a length over which a refractive index varies, the length being repeated along the axis of a pattern representing an optical grating, and it is characterized by a numerical parameter. In a case where the refractive index varies step-wise between two different values, a periodicity includes a duty cycle, which is the fraction of the period where a refractive index has a certain value rather than the other.

FIG. 1 illustrates the parameters used to describe the periodicity of a DSG, according to embodiments. The pattern 125 of a DSG is a variation in its refractive index. In general, the variation can be gradual or step-wise, but in FIG. 1, a step-wise variation between a refractive index n₁ 108 of a first material, and a refractive index n₂ 109 of a second material is shown. The variation, and overall periodicity, can be described as the final result of: a first periodicity 110 sampling a base pattern 105, resulting in a first pattern 115, and then a second periodicity 120 sampling the first pattern 115, the final result being the pattern 125 describing the DSG. The base pattern 105 has a base spatial period Λ₀ 107. The first periodicity 110 has a first spatial period Λ₁ 112 and a first duty cycle ΔΛ₁ 114, and the second periodicity 120 has a second spatial period Λ₂ 122 and a second duty cycle ΔΛ₂ 124. A duty cycle for the base grating can be defined mathematically as

$${p}_{0} = \frac{{ΔΛ}_{0}}{{Λ}_{0}}$$

where ΔΛ₀ is the length of the first material with refractive index n₁. In an embodiment, the duty cycle p₀ of a base grating can be p₀=0.5.

Parameters of a first step-wise periodicity 110 sampling the base pattern 105 include a period Λ₁ 112 for sampling the base pattern 105, and a duty cycle p₁ 114 which determines the width of each sampled part (i.e. each sampling) of the base pattern. A duty cycle for first periodicity 110 can be defined mathematically as:

$${p}_{1} = \frac{{ΔΛ}_{1}}{{Λ}_{1}}$$

where ΔΛ₁ is the length of each sampling of the base pattern 105. Because the first periodicity 110 is step-wise, a step corresponds to a sampling 111 of the base pattern 105, and an absence of a step corresponds to no sampling 113 of the base pattern 105.

Parameters of a second periodicity 120 can include a period Λ₂ 122, as well as a duty cycle p₂ 124 which determines the width of each sampled part (i.e. each sampling) of the first pattern 115. The duty cycle of a second periodicity 120 can be defined mathematically as:

$${p}_{2} = \frac{{ΔΛ}_{2}}{{Λ}_{2}}$$

where ΔΛ₂ is the length of each sampling of the first pattern 115. Because the second periodicity 120 is step-wise, a step corresponds to a sampling 121 of the first pattern 115, and an absence of a step corresponds to no sampling 123 of the first pattern 115

The result of applying the first periodicity 110 to the base pattern 105, and then applying the second periodicity 120 to the first pattern 115, is the pattern 125 that, when the variation is that of a refractive index, describes a DSG, the parameters of which pattern can be used to produce a DSG.

To summarize FIG. 1, the parameters defining the refractive index pattern 125 of a step-wise DSG include:
refractive index n₁;
refractive index n₂;
period Λ₀;
duty cycle p₀;
period Λ₁;
duty cycle p₁;
period Λ₂; and
duty cycle p₂.

The overall periodicity of the pattern 250 cannot be shown in FIG. 1, because a corresponding period would be much longer that the parts shown and the width of the drawing.

In embodiments, a base grating is a medium which has a refractive index that varies periodically along an axis of the medium. The variation can be gradual (such as a spatial sine wave) or step-wise (such as a spatial square wave). The periodic variation of the refractive index along an axis of the medium can gradually follow a sinusoidal wave from a minimum refractive index to a maximum refractive index repeatedly. Alternatively, the periodic variation of the refractive index along an axis of the medium can be substantially step-wise, as if there were two distinct refractive indices corresponding to two distinct materials. In either case, the base grating has an “effective refractive index”, the value of which is between its minimum refractive index and its maximum refractive index. The effective refractive index can characterize the base grating as a whole, in particular as to how much phase delay the base grating can cause to an optical wavelength, compared to vacuum.

A medium having a gradually changing, periodic refractive index can be described with the mathematics of sinusoidal waves. However, a medium having a step-wise periodic refractive index can be more suited to be produced in practice, because it can be produced with two different materials. A medium with two distinct materials and which has a step-wise periodic refractive index can be seen as a square spatial wave, and it can also be described with the mathematics of waves. Some aspects of periodicity can be more easily described with a sinusoidal wave pattern, such as interference and the “beating effect” described further below mathematically, and which is known to those skilled in the art of wave behavior, while other aspects can be more easily described with a square wave pattern, such as a “duty cycle”). Embodiments include a DSG comprising a medium having a periodic refractive index the pattern of which is a sinusoidal wave pattern or a substantially square wave pattern. Those skilled in the art of wave behavior and Fourier analysis will recognize that a square wave pattern is a limiting case of multiple, overlapping sinusoidal wave patterns. Regardless of whether a medium has a periodic refractive index the pattern of which is a sinusoidal or substantially square-shaped pattern, the periodic aspect of the pattern can be similar, and in particular, a sinusoidal-wave pattern and a square-wave pattern can each have similar characteristics of periodicity. If a sinusoidal wave and a square wave pattern have the same characteristics of periodicity, their properties, such as their reflective spectra, can also be similar.

A single-sampled grating (SSG) can refer to a grating in which the minimum refractive index is the minimum refractive index of a base grating, and an effective maximum refractive index of the grating is the effective refractive index of the base grating. Because the effective maximum refractive index of the grating is from the base grating, the base grating is said to be “sampled”, in accordance with a first period and a first duty cycle. Alternatively, a SSG can refer to a grating in which an effective minimum refractive index of the grating can be the effective refractive index of the base grating, and the maximum refractive index of the grating can be the maximum refractive index of the base grating. Either case defines a periodic sampling of the base grating.

A dual-sampled grating (DSG) can refer to a grating in which the minimum refractive index is the minimum refractive index of a SSG, and an effective maximum refractive index of the grating is the effective refractive index of the SSG. Because the effective maximum refractive index of the grating is from the SSG, the SSG is said to be “sampled”, in accordance with a second period and a second duty cycle (or for brevity: the base grating is “dual-sampled”). Alternatively, a DSG can refer to a grating in which an effective minimum refractive index of the grating can be the effective refractive index of the SSG, and the maximum refractive index of the grating can be the maximum refractive index of the SSG. Either case defines a periodic sampling the SSG.

To produce or manufacture a DSG, the refractive indices and periodicity parameters of the DSG's should first be determined via simulations making use of classical optics theory as known to a person of ordinary skill in the art of wave behavior. For example, one can design a base Bragg grating by selecting two different refractive indices and have them alternate according to a base period 107 and a base duty cycle. Then, a first periodic sampling of the base grating can be taken with a first spatial period and first duty cycle (i.e. a sampling periodicity 110). Then, a second periodic sampling (with a sampling periodicity 120) can be taken of the result, the second periodic sampling having a second spatial period and a second duty cycle. These periodic sampling parameters, as described in FIG. 1, as well as the two refractive indices, can be inputs for optics theory calculations that can produce a reflection spectrum as an output. Depending on the output reflection spectrum, the parameters can be further adjusted until a desired reflection spectrum is achieved, and then those parameters can be used for the production of a DSG. A search for parameters giving rise to a desired optical spectrum can also be formulated as an optimization problem that can be solved numerically.

In some embodiments, a DSG can be produced with photolithography. In other embodiments, a DSG can be produced by stacking films via one or more thin film deposition techniques. In either case, the DSG's parameters should be known beforehand, as determined with calculations.

To produce a DSG with a photolithography process, electron beam lithography (EBL) and/or standard photolithography (SPL) can be used to inscribe the pattern determined with simulations, onto a physical wafer.

A photolithography process can start by applying a uniform top layer made of a different material A, having a refractive index n₁, onto a wafer of material B, having a different refractive index n₂. The wafer can be spin-coated with a photoresist, such as a chemical gel comprised of ring molecules.

Once the photoresist has been spin-coated onto the material A, a focused electron beam can be introduced to scan (i.e. “inscribe”, “write”, or “shine”) the pattern 105 of a base Bragg grating, line-by-line, on the photoresist. The energy from such scanning electrons can cause the ring molecules of the photoresist to open up, in a process referred to as “exposure”. At this point, the pattern of the base Bragg grating is inscribed, but it is not yet developed.

Then, by dipping the exposed wafer into an alkaline solution, the scanned, opened-ring molecules of the photoresist can be resolved by the alkaline solution, whereas the unexposed ring molecules can be unaffected. This step can be referred to as development. As such, the non-scanned surfaces of material A having refractive index mi are shielded with photoresist, and the scanned surfaces become opened to ambient air.

Then, with either chemical etching (with an acid solution), or with physical etching (ion beam bombardment), unprotected parts of material A can be removed, while the photoresist-protected parts of material A surface can remain.

Then, a material B can be deposited on top of the wafer to fill the voids left from removing material A, thereby resulting in a base Bragg grating with materials A and B having respective refractive indices n₁ and n₂.

Once a base Bragg grating is formed, it can be used as a wafer for a further, similar photolithography process, to apply a first periodic sampling 110. Because the period and duty cycle of a periodic sampling 110 is typically much greater than the period and duty cycle of the pattern 105 of a base Bragg grating, an electron beam is not required to achieved the required resolution and the focused beam of electron and corresponding photoresist can be replaced with a focused beam of ultraviolet light and corresponding photoresist, which are more common. The result of completing a photolithography process with a first periodic sampling 110 on a base Bragg grating can be a single-sampled grating (SSG).

In an embodiment, an SSG as above can be used as a wafer for yet a further photolithography process, to apply a second sampling periodicity. However, alternatively, a second sampling periodicity can be applied with a second scanning of ultraviolet light onto the same photoresist, before development and etching of the first sampling periodicity, such that when the device is developed and etched, both the first periodic sampling and the second periodic sampling are applied, and a dual-sampled grating (DSG) is revealed, thus bypassing a complete production of an intermediate single-sampled grating (SSG).

Alternatively, by using a photoresist that is sensitive to both a scanning electron beam and an ultraviolet light beam, the base Bragg grating, the first sampling periodicity and the second sampling periodicity can be inscribed before development and etching, such that a single development step and a single etching step can reveal a completed DSG without a complete base Bragg grating structure and a complete SSG structure ever being produced.

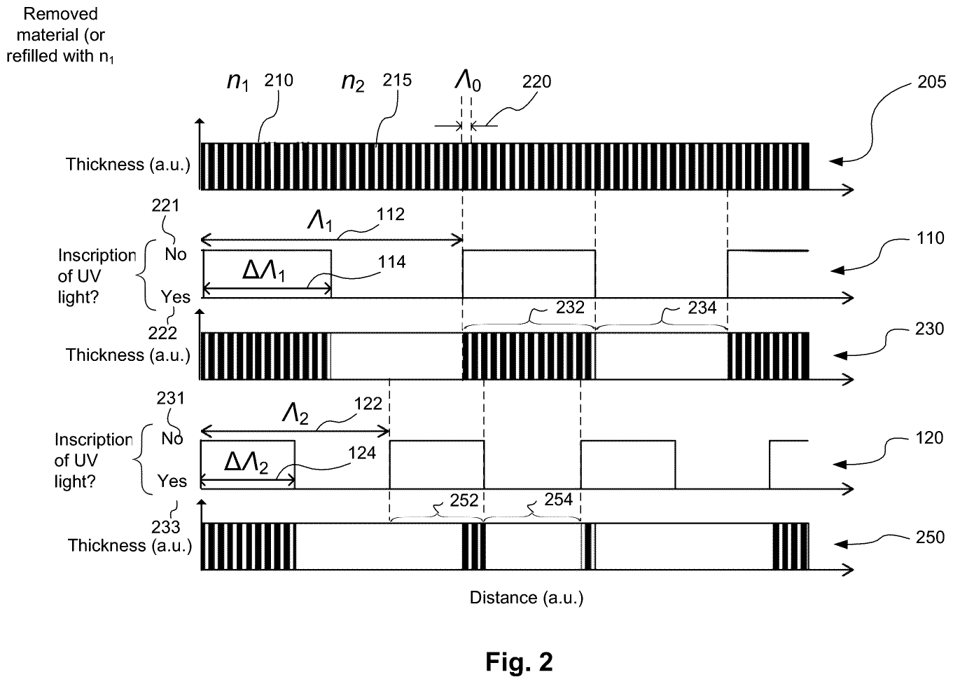

FIG. 2 illustrates physical gratings manufactured from inscribing the patterns of FIG. 1, according to embodiments of the present disclosure. A base grating 205 can include a material A with a refractive index n₁ 210, a material B with a refractive index n₂ 215, and a periodicity Λ₀ 220 at which the two refractive indices alternate. A base grating 205 can be produced by applying the pattern 105 of a base Brag grating with photolithography using an appropriate photoresist and focused beam of electrons to inscribe the pattern 105. The photoresist can be removed with an appropriate solution, and the underlying material A with refractive index n₁ 210 can be removed with chemical etching (with an acid solution), or with physical etching (ion beam bombardment). Then, the resulting cavities can be filled with material B with a refractive index n₂ 215, using one of many deposition techniques known in the art of photolithography, thus forming the base Bragg grating 205 with base Bragg grating pattern 105.

A base grating 205 can be sampled with a first periodicity 110 to form an SSG (i.e. a once-sampled grating). To do so, a photoresist suited for ultraviolet (UV) light can be applied onto the base Bragg grating 205 and the first periodicity 110 can be inscribed onto the photoresist. Then, UV light can be used to inscribe 222 the first periodicity 110, to the photoresist and the device can be dipped into an alkaline solution to remove the photoresist. This step is called development. After development, etching can be used to remove parts of the base Bragg grating uncovered by photoresist, leaving voids 234, while samplings 232 of the base Bragg grating 205, covered by uninscribed 221 photoresist remain. The result is a structure 230 comprising samples 232 of the base Bragg grating 205, spaced out according to the period 112 and duty cycle 114 of the first periodicity 110. The voids 234 can be refilled with material B at this stage or later.

Before the photoresist is developed and etched out, a second periodicity 120 can be inscribed, such that one development step and one etching step results in a DSG with cavities that can be filled material B to produce the DSG as designed. However, an intermediary SSG 230 can be completed or partially completed, before a second periodicity 120 is inscribed.

Regardless of whether an intermediary, temporary SSG is produced, and whether developments and etching are applied after each inscription, the result is a DSG having a pattern defined by the base periodicity, the first periodicity, and the second periodicity. The pattern of the DSG includes samplings 252 of an intermediary SSG 230 (which is some embodiments is not fully produced), that were under uninscribed 231 photoresist, and voids 254 resulting from material being removed for being under inscribed 233 photoresist. Any void 254 resulting from etching can be refilled with a material B having the desired refractive index, such as to implement parameters defining the refractive index pattern of a step-wise DSG as designed, i.e.:
refractive index n₁;
refractive index n₂;
period Λ₀;
duty cycle p₀;
period Λ₁;
duty cycle p₁;
period Λ₂; and
duty cycle p₂.

In other embodiments, thin films of at least two different materials, having thicknesses mapping the pattern 125 of a DSG with pre-calculated parameters, can be deposited as a stack of layers, using one or more a thin film deposition processes, and the resulting stack of films would be a DSG 250. In other embodiments, other manufacturing techniques can be used to produce a DSG as disclosed herein.

Because the pattern 125 of a DSG according to embodiment can be predefined according to calculations resulting in a desired reflection spectrum, a manufactured DSG can be used to generate a reflection spectrum in an optical device such as, but not limited to, a wavelength division multiplexer, a wavelength division demultiplexer, an optical sensor, a mode-locked laser, and more.

A DSG according to embodiments can be used as an optical filter includes a DSG and that reflects and transmits (i.e. filters) optical wavelengths in ratios that depend on a base period, a first sampling period, a second sampling period, as well as a first duty cycle for the first sampling period, and a second duty cycle for the second sampling period.

In another embodiment, an optical filter can include two DSGs interfaced with each other, the base period, two sampling periods and two duty cycles of one of the two DSGs can be different from the base period, two sampling periods and two duty cycles of the other of the two DSGs, and the reflection and transmission spectra of the two DSGs can depend on the two base periods, the two first sampling periods, the two second sampling periods, the two first duty cycles, and the two second duty cycles. Further, by applying a current, voltage, heat, or mechanical pressure to at least one of the two DSGs, the effective refractive index of the at least one of the two DSGs can change such as to tune the transmission spectrum of the at least one of the two DSGs If the reflection spectra of the two DSGs include peaks of reflection for certain optical wavelengths, the application of a current, voltage, heat or mechanical pressure to at least one of the two DSGs can shift reflection peaks to a common optical wavelength, thereby filtering the optical wavelength at that reflection peak from other reflection peaks. The shifting of reflection peaks from two different DSGs until a reflection peak of one of the two DSGs has the same optical wavelength as a reflection peak of the other DSG of the two DSGs is similar to a Vernier effect used in a Vernier scaled caliper, where a result is obtained where a numbered marking on one scale is aligned with a numbered marking of an adjacent, different scale, and other markings of the scales are misaligned.

In an embodiment, an optical device includes a front DSG and a rear DSG, and the optical device can be used as a wavelength filter. The reflection spectrum of the front and rear DSGs can have slightly different FSRs, such as to allow a Vernier effect when respective tunings are applied to the front and rear DSGs, such as current, heating or electric field tunings. If light is provided at the front face of such an optical device, a Vernier effect can result in light being reflected by the optical device being very monochromatic, while light transmitted by the optical device including wavelengths other than the reflected wavelengths.

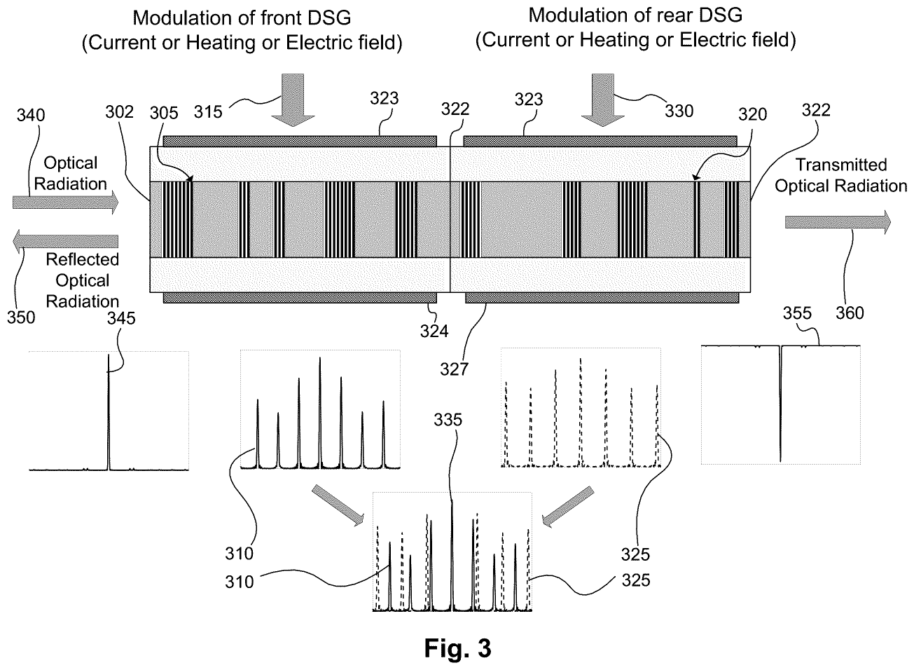

FIG. 3 illustrates a tunable optical filter according to an embodiment of the present disclosure. The tunable optical filter 300 includes a front DSG 305 and a rear DSG 320, both of which can share a common interface 322. The lack of a medium between the front and rear DSGs 305, 320 can limit optical losses or other influences caused by such intermediate medium.

Once the parameters of their respective patterns have been determined theoretically, the front DSG 305 and the rear DSG 320 can be manufactured separately with photolithography as the DSG 250 of FIG. 2, and then combined. Alternatively, films can be stacked into a single layered structure, in accordance with the parameters of their respective patterns.

If the manufacturing process involves photolithography, the two DSG patterns can be determined with simulations (to obtain desired reflection spectra), and the patterns can be programmed into an scanning electron beam emitter and/or UV beam emitter, such that both DSG patterns can be inscribed adjacent to each other onto one same wafer. Once the two adjacent DSG patterns have been inscribed onto a wafer, the subsequent lithography steps of development and etching can be performed once and the final device can be one part containing both DSGs.

When optical radiation (e.g. light) 340 is input to a face 302 of the front DSG 305, different wavelengths of the optical radiation (e.g. light) 340 can be transmitted or reflected according to the reflection spectrum 310 of the front DSG 305, and the reflection spectrum 325 of the rear DSG 320. The optical radiation (e.g. light) 340 is therefore split into reflected optical radiation (e.g. light) 350 and transmitted optical radiation (e.g. light) 360, in accordance with a reflection spectrum 335 combining the reflection spectrum 310 of the front DSG 305, and the reflection spectrum 325 of the rear DSG 320. The face 302 of the front DSG 305 therefore receives optical radiation (e.g. light) 340 and also outputs the reflected optical radiation (e.g. light) 350. Similarly, the rear face 322 of the DSG 320 is an output for optical radiation (e.g. light) 360 transmitted out of the optical filter 300.

To provide tunability of the reflected optical radiation (e.g. light) 350 and the transmitted optical radiation 360, the reflection spectrum 310 of the front DSG 305, and the reflection spectrum 325 of the rear DSG 320 can be tuned separately, by modulating a medium of the front DSG 315 and by tuning a medium of the rear DSG 330. To do so, the optical filter 300 has a first electrical contact pad 323 above the front DSG 305 and a second electrical contact pad 324 below the front DSG 305, a third electrical contact pad 326 above the rear DSG 320 and a fourth electrical contact pad 327 below the rear DSG 305. By providing separate currents to the front and rear DSGs, the reflection spectra of the front DSG 305 and the rear DSG 320 can be shifted separately until a wavelength of the optical radiation 340 (e.g. light) input to the optical filter is reflected by one DSG is similarly reflected by the other DSG, i.e., until a reflection peak of one respective spectrum overlaps with a reflection peak of the other reflection spectrum.

The tuning of a medium of a DSG (i.e. the tuning of a medium of the front DGS 305 and tuning of the medium of the rear DSG) can refer to tuning an effective refractive index of the DSG with a current, electric field, or heat. Therefore, in some embodiments, a voltage can be applied to the first, second, third, and fourth electrical contact pads 323, 324, 326 327 instead of a current. In other embodiments, instead of the first, second, third, and fourth electrical contact pads 323, 324, 326 327, the tunable optical filter 300 includes a first heating pad above the front DSG 305, a second heating pad below the front DSG 305, a third heating pad above the rear DSG 320, and a fourth heating pad below the rear DSG. Heat can be applied to the first, second, third, and fourth heating pads to tune the mediums of the front and rear DGSs 305, 320.

Embodiments of the present disclosure include a laser cavity with a first DSG as a front mirror and a second DSG as a rear mirror. If one of the two DSGs is partially transparent, the laser cavity can be a laser source, wherein the exterior face of the partially transparent DSG is an output for an optical wavelength (i.e. laser) resonating in the laser cavity.

If the periodicities of the refractive index of the DGSs of an optical filter or a laser source are slightly different, an optical wavelength can be selected with a Vernier effect by which a reflection peak of the first DSG (i.e. the front mirror) can overlap with a reflection peak of the second DSG (i.e. the rear mirror), the overlapping reflection peaks being dependent on phase shifts applied in the first and second DSGs (i.e. the front and back mirrors).

With a Vernier effect, the wavelength tuning range of the laser cavity can be broadened by a factor of ξ (xi):

$$ξ = \frac{{Δλ}_{r}}{{Δλ}_{r} - {Δλ}_{f}} > 1$$

where Δλᵣ is the FSR of the second DSG (i.e. the rear mirror) and Δλ_{f} is the FSR of the first DSG (i.e. the front mirror), the FSR for each DSG being the wavelength spacing between adjacent reflection peaks. It is therefore beneficial for the two FSRs to be close apart.

By using SSGs, ξ can in practice reach 3 to 10, corresponding to a wavelength tuning range in the order of 30 nm to 100 nm. However, a laser source with SSGs cannot be directly modulated at high-speed, because the laser cavity is much too long. For example, an SSG DBR laser can have a total length of approximately 1.8 mm, almost 10 times longer than a conventional DFB or DBR laser that can be directly modulated with a −3 dB bandwidth of 10 to 20 GHz. A laser source with a laser cavity comprising two DSGs as mirrors according to embodiment, instead of two SSGs as mirrors, can be made shorter and thus be directly modulated at a higher speed (i.e. higher frequency).

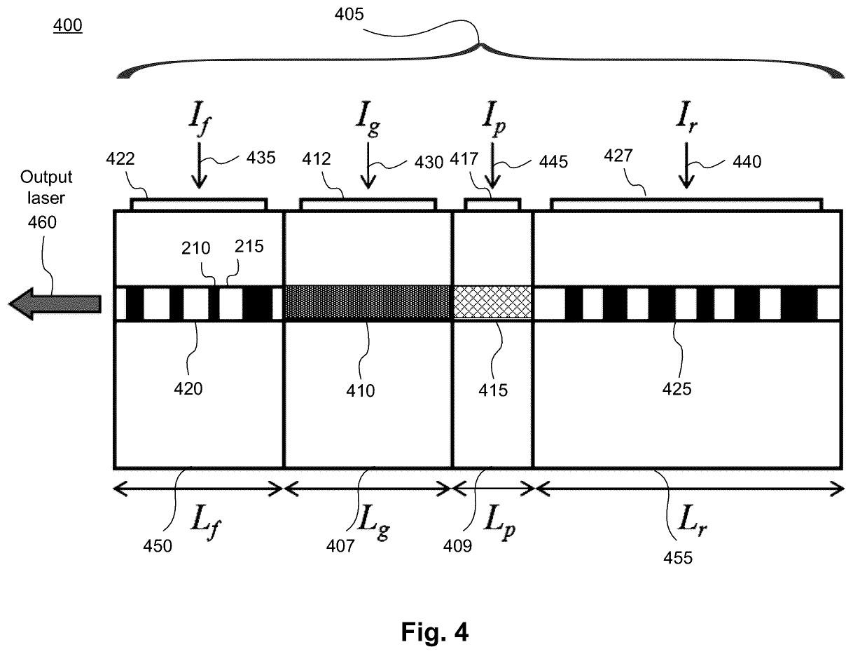

FIG. 4 illustrates a wideband wavelength tunable directly modulated laser (DML) source, with dual-sampled gratings as mirrors, according to embodiments. The wideband wavelength tunable DML source 400 includes a laser cavity 405 composed of four regions: a gain region 407 comprising a gain medium 410 with length L_{g}, a phase tuning region 409 comprising a phase tuning medium 415 with length Lₚ, a front grating section 450 comprising a front DSG 420 as a front mirror with length L_{f}, and a rear grating section 455 comprising a rear DSG 425 as a rear mirror with length Lᵣ. Each DSG 420, 425 can have multiple layers, and each layer can be made of a different material having a respective refractive index. For example, the front DSG 420 can be made of a first material 210 and a second material 215, each one having a respective refractive index. The pattern of the periodic refractive index of each DSG can be defined by a base period, a first sampling period, and a second sampling period, as well as a base duty cycle, a first duty cycle and a second duty cycle as described in FIG. 1, but these are not shown in either FIG. 1 or FIG. 4.

An external bias current can be injected into any one or each one of the gain medium 410, the phase tuning medium 415, the front DSG 420 and the rear DSG 425, via respective electrical interface materials (i.e. pads): an electrical interface material 412 for receiving an external bias current and injecting the external bias current into the gain region 407, an electrical interface material 417 for receiving an external bias current and injecting the external bias current into the phase tuning region 409, an electrical interface material 422 for receiving an external bias current and injecting the external bias current into the front grating region 450, and an electrical interface material 427 for receiving an external bias current and injecting the external bias current into the rear grating section 455. External bias currents can be generated by one or more external power supplies, such as one or more batteries. An external bias current I_{g} 430 can be injected into the gain medium 410 via the gain region 407 and the electrical interface material 412 to provide the gain required for light amplification and stimulated emission of radiation (i.e. namesake of “laser”), as well as modulation of the amplification and stimulated emission of radiation. For tuning the optical wavelength resonating in the laser cavity 405, an external bias current I_{f} 435 can be injected into the front grating region 450 via the electrical interface material 422, and an external bias current Iᵣ 440 can be injected into the rear grating region 455 via the electrical interface material 427. By injecting external bias currents I_{f} 435 and Iᵣ 440 into the front and rear grating regions 450, 455, respectively, local periodic refractive indices of the front and rear DSGs 420, 425, can be tuned. Tuning the periodic refractive indices of the front and rear DSGs 420, 425 in turn shifts the reflection spectra of the front and rear DSGs 420, 425. Alternatively, the laser source 400 may include a first thermal pad (not shown) near the front grating region 450 and the periodic refractive index of the front DSG 420 can be tuned by temperature changes. The laser source 400 may also include a second thermal pad near the rear region 455 and the periodic refractive index of the rear DSG 425 can also be tuned by temperature changes. If a reflection peak of an optical wave from the front DSG 420 and a reflection peak of an optical wave from the rear DGS 425 are at a same optical wavelength, that optical wavelength will resonate while other optical wavelengths may not. The effect is reminiscent of a Vernier effect, and it can allow selection of the lasing optical wavelength for the laser source 400.

A current Iₚ 445 can be injected into the phase tuning medium 415, via the electrical interface material 417 and phase tuning region 409, to align the grating-selected lasing mode with the natural cavity mode, where a “mode” (generally: a “mode of oscillation”) refers to a mathematical function describing an optical wave propagating in, and sustained by, the laser cavity, as well as the physical optical wave itself. While external bias currents I_{f} 435 and Iᵣ 440 can provide the grating-selected lasing mode having the greatest amplitude reflection (or the lowest laser cavity loss, and consequently the lowest threshold gain), an external bias current Iₚ 445 can determine the phase matching conditions, in that by tuning a current or voltage in the phase tuning medium 415, the phase of propagating optical waves can be tuned such that subsequently reflected optical waves are in phase with earlier reflected optical waves. As such, stable lasing conditions can occur when the light experiences a phase-matched round trip with minimum loss, inside the laser cavity 405 at the chosen wavelength.

For output laser 460 to be extracted from the lasing cavity, the reflectivity of the front DSG 420 in the front grating region 450 can be made lower than the reflectivity of the rear DSG 425 in the rear grating region 455, such as to increase its transparency. The amplitude and power of the output laser 460 can be directly modulated by changing the external bias current I_{g} 430 applied on electrical interface material 412 which is injected into the gain region 407. In some embodiments, the front DSG 420 is partially transparent to propagating optical waves sustained inside the laser cavity 405, to enable emission of the output laser 460.

To produce a DML with DSGs as mirrors, a process can begin by simulating each DSG until they produce desired reflection spectra. Then, the DSGs' pattern parameters can be entered into an electron beam emitter and each physical DSG can be produced with electron-beam and/or UV lithography, as described with FIG. 2. An electron beam emitter, programmed with the parameters of the desired pattern, can be used to inscribe the pattern of base Bragg grating 205 onto a material 215 with refractive index n₂, topped with an appropriate photoresist. The inscription can have a base period Λ₀ 220, such that when inscribed parts are removed by etching, the cavities can be filled with a material 210 having refractive index n₁. The duty cycle of a base Bragg grating can be 0.

A lithographic process can be for a pattern that includes a first sampling 110 of the base Bragg grating 205, with a period Λ₁ 112 and a duty cycle p₁, the result of which can be a single-sampled grating 230.

To obtain the pattern of a DSG according to an embodiment, the SSG 230 can be sampled with a second period Λ₂ 122, and a second duty cycle p₂, based on a second sampling period 120. In an embodiment, the second sampling period Λ₂ 122 can be shorter than the first sampling period Λ₁ 112. Alternatively, the first and second sampling can be included in one pattern programmed into a lithography light, such that inscription onto the device includes both sampling periodicities and a DSG can be produced without the production of an intermediary SSG, thereby reducing the number of development, etching and cavity filing steps.

In an embodiment, a DML can be produced by stacking thin films, instead of lithography. In this case, the DML can be referred as a vertical cavity surface-emitting laser (VCSEL).

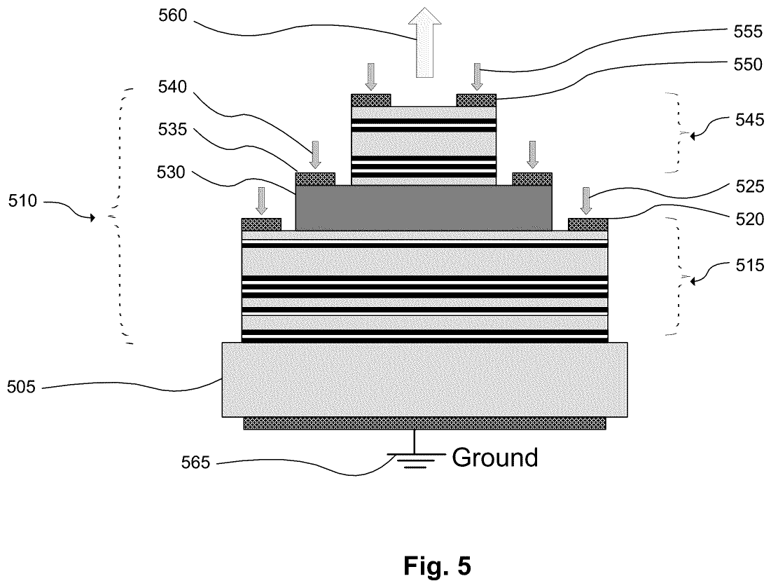

FIG. 5 illustrates a cross-section of a vertical-cavity surface-emitting laser (VCSEL) including a front DSG and a rear DSG, according to an embodiment. The DSGs can be designed and described with the parameters defined with FIG. 1. The VCSEL 500 includes a substrate 505 and a stack of thin films 510 deposited on the substrate 505. The substrate 505 is structural support for the stack of thin films 510. The stack of thin films 510 is configured as a laser cavity. The stack of thin films 510 includes a rear DSG 515 and an input electrical contact pad 520 to which a current or voltage 525 can be applied to tune the effective refractive index of the rear DSG 515 and shift the spectral reflection peaks of the rear DSG 515. The rear DSG 515 acts as a rear mirror of the VCSEL. The VCSEL 500 also includes an active medium 530 on the rear DSG 515 to provide gain and/or phase matching to optical radiation (i.e. light) in the stack of thin films 510. Gain, i.e. light amplification by stimulated emission of radiation (“laser”), can be provided via input electrical contact pads 535 to a gain medium 530, via an input bias current or voltage 540. Similarly, phase matching to improve interference between propagating optical waves can be provided via input electrical contact pads to a phase matching medium (not shown). The stack of thin films 510 also includes a front DSG 545 on top of an active medium 530. The front DSG 545 acts as a front mirror. The front DSG 545 includes input electrical contact pads 550 to which a current or voltage 555 can be applied to tune the effective refractive index of the front DSG 545 and shift the spectral reflection peaks of the front DSG 545. By making the front DSG 545 partially transparent to lasing wavelengths, optical radiation (e.g. light) generated by the active medium 530 or entering the VCSEL can be amplified by the active medium 530 and/or phase-matched by the phase tuning medium, and be reflected and partially reflected multiple times by the front and rear DSGs 515, 545, such that output radiation (e.g. light) 560 can contain amplified (lasing) wavelengths as determined by the reflection spectra of the front and back DSGs 545, 515. A ground 565 coupled to the substrate 505 can serve as a reference potential.

A grating such as a DSG made of two different mediums can be regarded as a single medium with an effective refractive index identified as n_{eff}, and the peak reflection wavelength λ_{B} of a base Bragg grating 205 can be:

$${λ}_{B} = 2 {n}_{eff} {Λ}_{0} \qquad ( A )$$

In an embodiment, a periodic refractive index can be a square spatial wave as in a Bragg grating 205, but it can also be sinusoidal, in which case it can be represented as a proportionality with a sinusoidal function such as a cosine function:

$$n ( z ) ∝ cos ( \frac{2 π}{{Λ}_{0}} z )$$

The sampling of the Bragg grating 205 can be represented as a multiplication with a sine wave having a period Λ₁ 112. This causes what is known in the art of wave behavior as a beating effect, i.e. a long periodicity Λ₁, overlapped with a short periodicity Λ₀ (i.e. if it were an acoustic musical note, the short periodicity Λ₀ would be the note, and the long periodicity Λ₁ would be an audible beating effect in time, due to interference oscillating from constructive to destructive):

$$n ( z ) ∝ cos ( \frac{2 π m}{{Λ}_{1}} z ) cos ( \frac{2 π}{{Λ}_{0}} z )$$

Because a single-sampled grating 230 is an overlap of a base Bragg grating 205, sampled with a periodicity 110, the reflected optical waves of a completed SSG can also be subject to a beating effect in which the beating effect results in reflection peaks at wavelengths λₘ for multiple orders of diffraction m, according to:

$${λ}_{m} = {λ}_{B} \frac{{Λ}_{1}}{{Λ}_{1} + m {Λ}_{0}} , ( m = 0 , \pm 1 , \pm 2 , … )$$

The spacing in the wavelength domain |Δλ_{SSG}| between adjacent reflection peaks of a SSG, can be called its free spectral range (FSR), and be determined with an FSR formula:

$$F S R ≡ \vert {Δλ}_{S S G} \vert \approx {Λ}_{0} \frac{{λ}_{B}}{{Λ}_{1}} = \frac{{λ}_{B}^{2}}{2 {n}_{eff} {Λ}_{1}} \qquad ( B )$$

According to eq. (B), for a central reflection wavelength λ_{B} that is fixed, the FSR can be determined by the sampling period Λ₁. Similarly, a sampling period Λ₁ can be selected to have a desired FSR by inverting eq. (B) as:

$${Λ}_{1} = \frac{{Λ}_{0} {λ}_{B}}{\vert {Δλ}_{S S G} \vert}$$

In an embodiment, wavelength tuning can be made continuous by reducing the FSR. According to eq. (B), the FSR can be reduced by making the sampling period Λ₁ 112 longer. However, for a sampling period Λ₁ 112 to be longer, an SSG, or a device such as a laser cavity using SSGs as mirrors must also be made very long, which can lead to a narrow modulation bandwidth.

In an embodiment, reducing the length of a laser cavity in for example, the laser cavity 405 of the laser source 400, can be done by periodically sampling 120 a SSG 230, such as with a period Λ₂ 122, and a duty cycle p₂ based on step-wise (i.e. square) samplings ΔΛ₂ 120. This can result in a DSG 250, according to an embodiment. In a case where the refractive index varies in a sinusoidal manner, this is like multiplying with a second overlapping period Λ₂:

$$n ( z ) ∝ cos ( \frac{2 π n}{{Λ}_{2}} z ) cos ( \frac{2 π m}{{Λ}_{1}} z ) cos ( \frac{2 π}{{Λ}_{0}} z )$$

While the above equation shows that beating can occur when the arguments of two or three cosines approach their maximum values, in an embodiment, any of the periodicities can be step-wise (i.e. square) or another shape that can be made from sinusoidal functions, as can be demonstrated with Fourier analysis known in the art of wave behavior.

In addition a DSG 250 having a second sampling periodicity 120, embodiments also include gratings having further sampling periodicities, which could be referred to as triple-sampled gratings (TSG), quadruple sampled gratings (QSG), and further multiple sampled gratings. Embodiments also include optical filters made with multiple sampled gratings, and DML made with multiple sampled gratings as cavity mirrors.

Similar to a SSG 230 having a beating effect, a grating made by periodically sampling 120 a pattern, that periodically samples 110 a base grating 205 can result in peak reflection wavelengths for multiple orders of diffraction m and n (not to be confused with refractive indices n₁ and n₂), according to:

$${λ}_{m , n} = {λ}_{B} \frac{{Λ}_{1} {Λ}_{2}}{{Λ}_{1} {Λ}_{2} + m {Λ}_{0} {Λ}_{2} + n {Λ}_{0} {Λ}_{1}} , ( m , n = 0 , \pm 1 , \pm 2 , … )$$

In an embodiment of a DSG 250, the extra degree of freedom n provided by a second sampling periodicity 120 can introduce additional reflection peaks. For orders (m, n)=(±1,0), and order (m, n)=(0, ±1), the FSR of a DSG can be similar to that of a SSG with period Λ₁:

$$F S R = \vert {Δλ}_{\pm 1 , 0} \vert = \vert {Δλ}_{0 , \pm 1} \vert \approx \frac{{λ}_{B}^{2}}{2 {n}_{eff} {Λ}_{1}}$$

However, for the additional peaks of a DSG, such as those defined by orders (m, n)=(±1, ∓1), the FSR between adjacent reflection peaks can be expressed with:

$$\vert {Δλ}_{- 1 , 1} \vert = \vert {Δλ}_{1 , - 1} \vert = \frac{{λ}_{B}^{2}}{2 {n}_{eff} {Λ}_{2}} \frac{\vert {Λ}_{1} - {Λ}_{2} \vert}{{Λ}_{1} {Λ}_{2}}$$

which, using eq. (A), can be rearranged into:

$$\vert {Δλ}_{D S G} \vert \approx {Λ}_{0} \frac{{λ}_{B} \vert {Λ}_{1} - {Λ}_{2} \vert}{{Λ}_{1} {Λ}_{2}} \qquad ( C )$$

Eq. (C) reveals that the FSR between adjacent reflection peaks of a DSG can be substantially proportional to the difference between the two sampling periods Λ₁ and Λ₂. In other words, the FSR including the additional peaks can be determined, not only by periods Λ₁ 110 and Λ₂ 122, but also by the difference between Λ₁ and Λ₂, i.e. by |Λ₁−Λ₂.

Indeed, by comparing eq. (C) and eq. (B):

$$\vert {Δλ}_{S S G} \vert \approx {Λ}_{0} {λ}_{B} \frac{1}{{Λ}_{1}} \qquad ( B )$$

$$\vert {Δλ}_{D S G} \vert \approx {Λ}_{0} {λ}_{B} \frac{\vert {Λ}_{1} - {Λ}_{2} \vert}{{Λ}_{1} {Λ}_{2}} \qquad ( C )$$

it can be seen that just like Λ₁ in eq. (B) is the sampling period 112 of a SSG, the following term of eq. (C) is effectively a sampling period of a DSG:

$$effective sampling period of a D S G = \frac{{Λ}_{1} {Λ}_{2}}{\vert {Λ}_{1} - {Λ}_{2} \vert}$$

By overlapping the first sampling period Λ₁ with a second sampling period Λ₂, an effective sampling period can be as above. Hence, to reduce the length of a DSG, both Λ₁ and Λ₂ can be made short, and the DSG's FSR can be tuned or shortened by adjusting the difference between Λ₁ and Λ₂. When compared to either of Λ₁ and Λ₂, the effective sampling period of a DSG is too long to be shown to scale in any of FIG. 1 to FIG. 5.

The FSR of a DSG 250 according to an embodiment can be adjusted by adjusting period Λ₁ 112, and period Λ₂ 122, and the difference |Λ₁−Λ₂|. In particular, the FSR of a DSG 250 can be tuned to be sufficiently short to be used as a mirror in the laser source 400, which can enable the laser cavity 405 of the laser source 400 to be shorter itself, and therefore be directly modulated at a higher speed (i.e. higher frequency).

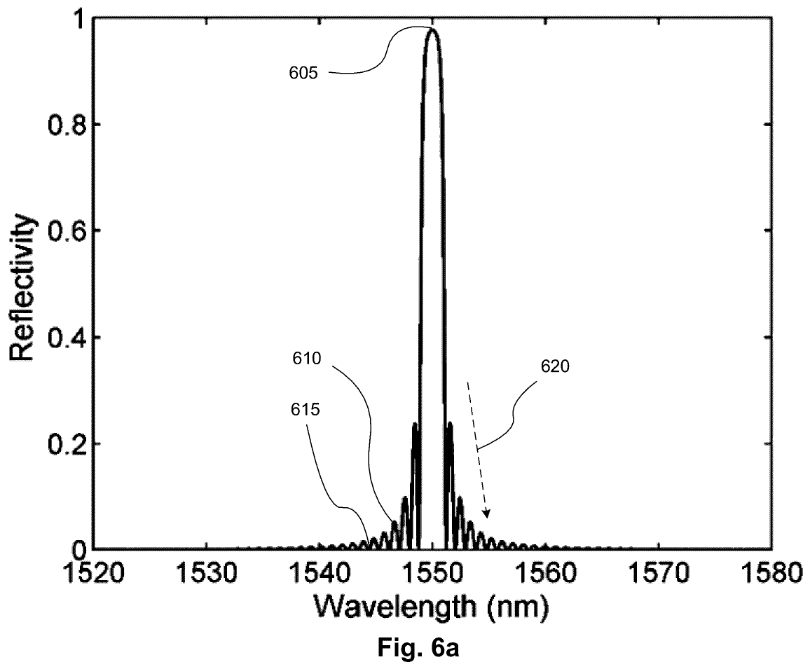

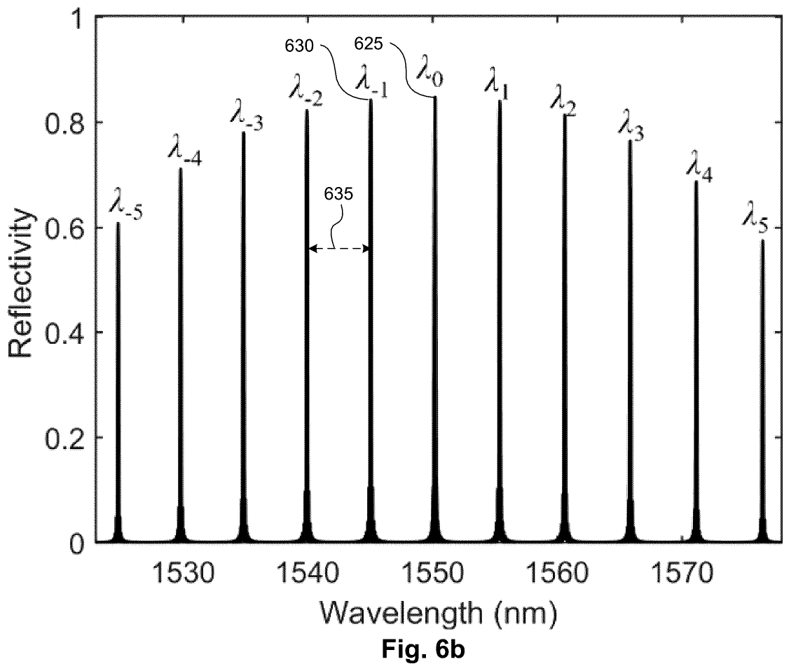

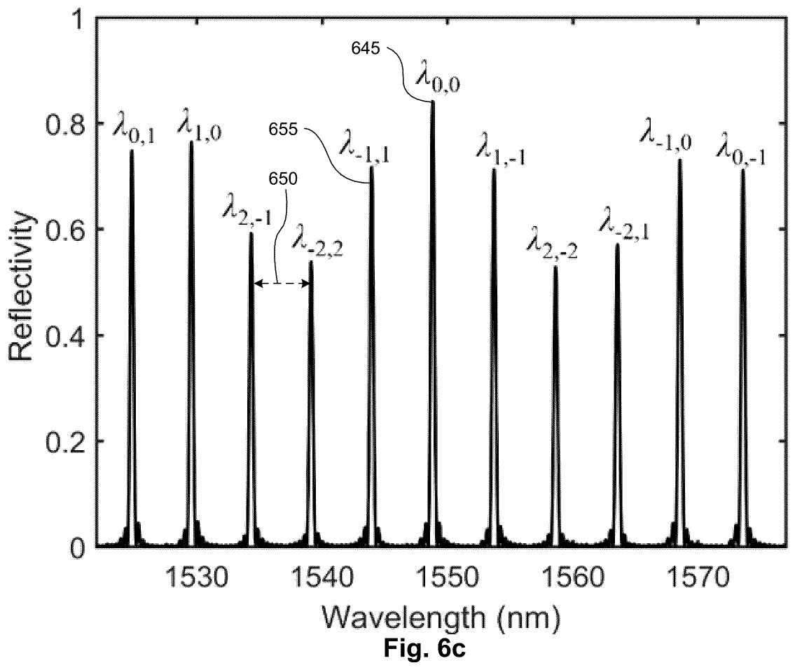

The reflection characteristics of a grating, such as a base grating, a SSG, and a DSG can be computed using a transfer matrix method (TMM). Results obtained for simulations of reflection characteristics of a base grating, a SSG, and a DSG are shown in FIG. 6a, FIG. 6b and FIG. 6c.

FIG. 6a is graph showing a reflection spectrum of a simulated base Bragg grating. The peak reflection wavelength 605 of the base grating results from eq. (A) with n_{eff}=3.2 and λ_{B}=1550 nm. As shown in the graph, on either side of the peak reflection wavelength 605, an interference spectrum is approximately symmetrical, with peaks of constructive interference 610 approximately as wide as bands of destructive interference 615. Away from the peak reflection wavelength 605, reflectivity drops sharply 620.

FIG. 6b is a graph showing a reflection spectrum of a simulated single-sampled grating (SSG). The central reflection wavelength 625 of the SSG is at the same wavelength λ_{B} as the peak reflection wavelength 605 of the sampled base grating), and the FSR 635 between adjacent reflection peaks is determined by the sampling period Λ₁ and central wavelength λ_{B}, according to eq. (B). By setting the FSR to |Δλ_{SSG}|=5 nm, and setting the SSG's duty cycle to p₁=0.1, a sampling period of Λ₁=75 μm can be obtained. The reflection spectrum of the SSG as a whole is reminiscent of a comb and can be said to be comb-shaped.

FIG. 6c is a graph showing a reflection spectrum of a simulated DSG of the present disclosure. The central reflection peak 645 at wavelength λ_{B} is again determined by the base Bragg grating and has an order of diffraction λ_{0,0} (m=0, n=0). To obtain the same FSR (5 nm) as the SSG of FIG. 6b, the sampling periods of the DSG can be set to Λ₁=15 μm and Λ₂=18.75 μm. These respectively correspond to ⅕ and ¼ of the sampling period (75 μm) of the SSG of FIG. 6b. In an embodiment, both duty cycles of the DSG can be set to 0.1, i.e. p₁=0.1 and p₂=0.1. The DSG can have an approximately symmetrical interference spectrum around the central reflection peak 645. The width of a band of destructive interference 650, between reflection peaks of constructive interference 655 can be referred to as the FSR of the spectrum.

If the duty cycles of the DSG of FIG. 6c (or of another DSG according to an embodiment) are set to p₁=0.5 and p₂=0.5 instead, the second order reflection peaks can disappear. Disappearing orders of diffraction k can follow the expression:

$$k = \frac{1}{p} {k}^{′} , ( {k}^{′} = \pm 1 , \pm 2 , … ) , ( \frac{1}{p} > 1 )$$

where p is a duty cycle.

In an embodiment of a laser source with DSGs as cavity mirrors, it can be useful for the FSR to be small. For example, in the laser source 400 in FIG. 4, if the FSR is small, it can be possible to cover many reflection peaks, over the range of refractive indices resulting from tuning (with a direct current, voltage, or temperature change). If SSGs are used as mirrors in the laser source, covering as many reflection peaks can require a longer sampling period Λ₁, as indicated by eq. (B). However, if DSGs are used as mirrors in the laser source instead, a similar number of reflection peaks can be obtained with two shorter sampling periods: Λ₁ and Λ₂. Consequently, the total length of DSG is smaller than the total length of an SSG having the same FSR, and using DSGs a mirrors in laser source enables the total length of a laser cavity of the laser source to be reduced, which in turn can enable high-speed (i.e. frequency) direct modulation of the laser emitted by the laser source.

In an SSG, for the FSR 635 to be small, and to allow a direct current to be injected into the SSG to tune the temperature and periodic refractive index of the SSG continuously, the sampling period Λ₁ can be chosen to be sufficiently long, as indicated by eq. (B). However, in a DSG according to embodiments, for the FSR 650 to be small, eq. (C) can be used instead. In this case, short sampling periods Λ₁ and Λ₂ can be selected to have a small difference. Doing so can cause the FSR 650 of a DSG to be as short as the FSR 635 of a SSG, but with the first sampling period 112 and the second sampling period 122 being much shorter than the sampling period 112 of an SSG. This provides a technical advantage in that the total length of an optical device (i.e. filter, laser source, etc.) having a DSG, can be reduced significantly, compared to an optical device having an SSG with the same FSR. In other words, for a given FSR, the length of a DSG can be shorter than the length of a SSG. This has the advantage of enabling higher speed (i.e. higher frequency) direct modulation of an optical device (e.g. a laser source), by using two such DSGs as mirrors at either end of a laser cavity of the optical device.

As an example, the pattern of a DSG 250 can include samples of a base Bragg grating 205 having the following parameters:
Base Bragg grating period Λ₀=242 nm,
Base Bragg grating duty cycle p₀=0.5,
a first material 210 having a refractive index n₁=3.211,
a second material 215 having a refractive index n₂=3.200.

The sampling parameters of the DSG 250 can be:
1^{st} sampling period 112 Λ₁=31.3 μm,
1^{st} duty cycle 114 p₁=0.5,
2^{nd} sampling period 122 Λ₂=20.9 μm,
2^{nd} duty cycle 124 p₂=0.5,
grating length L_{f}=200 μm.

In an embodiment of a DSG with these parameters, the central reflection wavelength of the DSG 120 is λ_{B}=1549 nm and the FSR, at orders of diffraction λ_{0,0}, λ_{±1,0}, λ_{0,±1}, and λ_{±1,∓1}, is:

$$\vert {Δλ}_{f} \vert = 6 nm$$

According to eq. (B), an SSG having the same FSR of Δλ_{f}=6 nm, would require a sampling period 112 Λ₁ to be 62.6 μm, instead of 31.3 μm. This highlights that to obtain a given FSR, the total length of a DSG 250 can be half the length of an SSG.

A laser source 400 according to an embodiment can include the preceding DSG 250 as a front DSG 450, and another DSG as a rear DSG 425. The parameters of the rear DSG 425, can be:
1^{st} sampling period 112 Λ′₁=37.5 μm,
duty cycle 114 p′₁=0.5,
2^{nd} sampling period 122 Λ′₂=25.0 μm,
duty cycle 124 p′₂=0.5,
grating length Lᵣ=400 μm.

With these numbers for the parameters of the rear DSG 425, the central reflection wavelength of the rear DSG 425 is at λ_{B}=1549 nm and the FSR at orders of (diffraction) λ_{0,0}, λ_{±1,0}, λ_{0,±1}, and λ_{±1,∓1} (FSR), is Δλᵣ=5 nm.

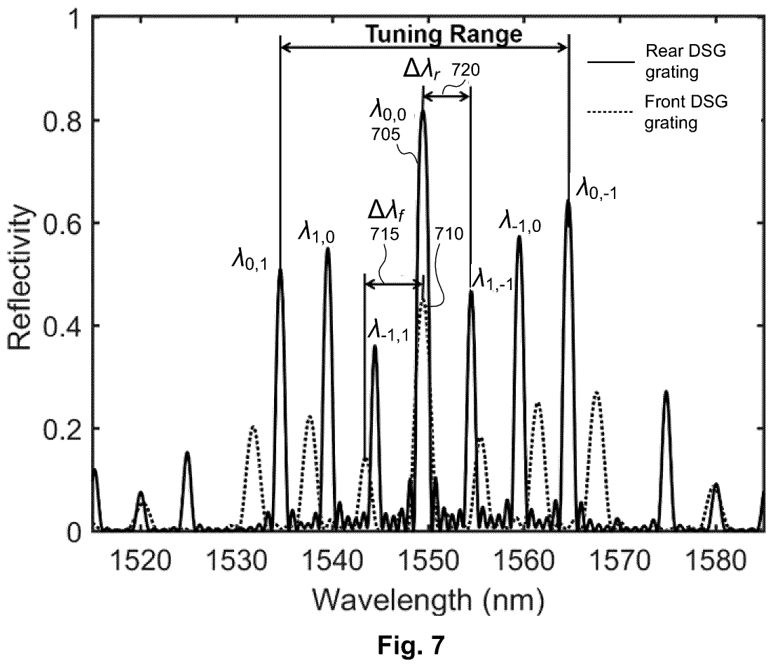

An SSG having the same FSR of Δλᵣ=5 nm would have a length of 75.0 μm. Again, this highlights that to obtain a given FSR, the total length of a DSG can be half the length of an SSG. The calculated reflection spectra for each of the front DSG 420 and the rear DSG 425, with the above parameters, are shown in FIG. 7, where they are overlapped.

FIG. 7 shows two overlapping reflection spectra: one for a DSG with parameters that result in an FSR of 5 nm, and the other for a DSG with parameters that result in a FSR of 6 nm, according to simulated embodiments. The solid line spectrum can be for the rear DSG 425 (i.e. the rear mirror) of the laser source 400 shown in FIG. 4, and the dashed line spectrum can be for the front DSG 420 (i.e. the front mirror) of the laser source 400 shown in FIG. 4.

The central wavelength 705 of the front DSG 420, and the central wavelength 710 of the rear grating 425, are both at 1549 nm. Furthermore, the FSR between adjacent reflection peaks of the front grating 420 is Δλ_{f}=6 nm 715, and that of the rear grating 425 is Δλᵣ=5 nm 720.

In an embodiment, the reflectivity of the front DSG 420 can be smaller than that of the reflectivity of the rear DSG 425, such that the output laser 460 from the laser cavity 405 is predominantly transmitted through the front DSG 420. By adjusting currents, bias voltages or local temperatures applied to the front grating region 450 and the rear grating regions 455, the two overlapping spectra of FIG. 7 can be shifted separately and when a reflection peak of one spectrum overlaps with a reflection peak of the other spectrum (Vernier effect), the wavelength where reflection peaks overlap will be the wavelength where laser radiation can occur. Phase-matching with the natural cavity mode, i.e. maximising constructive interference of optical waves at the selected wavelength, and therefore lasing can be achieved by adjusting a current, bias voltage or temperature in a phase tuning region 409 between the two mirrors. In an embodiment, the tuning range of the laser source 400 can be:

$$Δλ = \vert \frac{Δ {λ}_{f} Δ {λ}_{r}}{Δ {λ}_{f} - Δ {λ}_{r}} \vert = 30 nm$$

For a DSG according to an embodiment to achieve the same FSR as a SSG, the total length of the DSG can be, using the above parameters, 600 μm, instead of 1.2 mm. Considering that the length of the gain region 407 can be around 150 μm and the length of the phase tuning region 409 can be around 50 μm, the total length of a laser cavity 405 of the laser source 400 with the front and rear DSGs 420, 425 of the present disclosure can be reduced to approximatively 800 μm, from 1.4 mm, which would be a typical length for the laser cavity of a SSG-based laser source (i.e. a laser source having SSGs as mirrors).

For a laser source, such as laser source 400, to have a −3 dB modulation bandwidth in the neighborhood of a few GHz, a length of the laser cavity below 1 mm is often a necessary condition. An embodiment that includes the front and rear DSGs with the above parameters results in a laser source that can be directly modulated under a speed of up to approximately 2.5 Gbps.

A wideband tunable DML source comprising DSGs as mirrors according to embodiments can be directly modulated up to at least a speed (frequency) of approximately 2.5 Gbps, in a broad range (30 nm) of tunable optical wavelengths. A wideband tunable DML source according to embodiments can retain certain characteristics of a comparable laser source comprising SSGs as mirrors, such as threshold current, slope efficiency, output power, and others.

In another example, a laser source that includes DSGs according to embodiments, parameters of the DSGs can be selected to increase the lasing wavelength tuning range and the laser's −3 dB modulation bandwidth. This can be made possible by selecting shorter lengths for the front DSG 420 and the rear DSG 425.

The parameters of a base Bragg grating can again be:
Base Bragg grating period Λ₀=242 nm,
Base Bragg grating duty cycle p₀=0.5,
refractive index n₁=3.211,
refractive index n₂=3.200.

For a front DSG 420 having a pattern that samples the base Bragg grating above, the sampling parameters can be:
1^{st} sampling period 112 Λ₁=25.1 μm,
duty cycle 114 p₁=0.5,
2^{nd} sampling period 122 Λ₂=16.7 μm,
duty cycle 124 p₂=0.5,
front DSG length L_{f}=200 μm.

A DSG 420 according to an embodiment with the above parameters has a central reflection wavelength of Δλ_{B}=1549 nm, and at orders (of diffraction) λ_{0,0}, λ_{1±1,0}, λ_{0,±1}, and λ_{±1,∓1}, the FSR is Δλ_{f}=7 nm. To obtain an FSR of Δλ_{f}=7 nm with an SSG having a pattern sampling the same base Bragg grating, the sampling period would instead be Λ₁=50.2 μm.

For a rear DSG 425 having a pattern sampling the same base Bragg grating, the parameters can be:
1^{st} sampling period 112 Λ′₁=21.9 μm,
duty cycle 114 p′₁=0.5,
2^{nd} sampling period 122 Λ′₂=14.6 μm,
duty cycle 124 p′₂=0.5,
front DSG length Lᵣ=250 μm.

In an embodiment of rear DSG 425 with the above parameters, the central reflection wavelength of the rear DGS 425 is at Δλ_{B}=1549 nm, and the FSR, at orders (of diffraction) λ_{0,0}, λ_{1±1,0}, λ_{0,±1}, and λ_{±1,∓1}, is Δλᵣ=8 nm. To obtain an FSR of Δλᵣ=8 nm with a SSG sampling the same base Bragg grating, the sampling period would be 43.8 μm, instead of 21.9 μm as above.

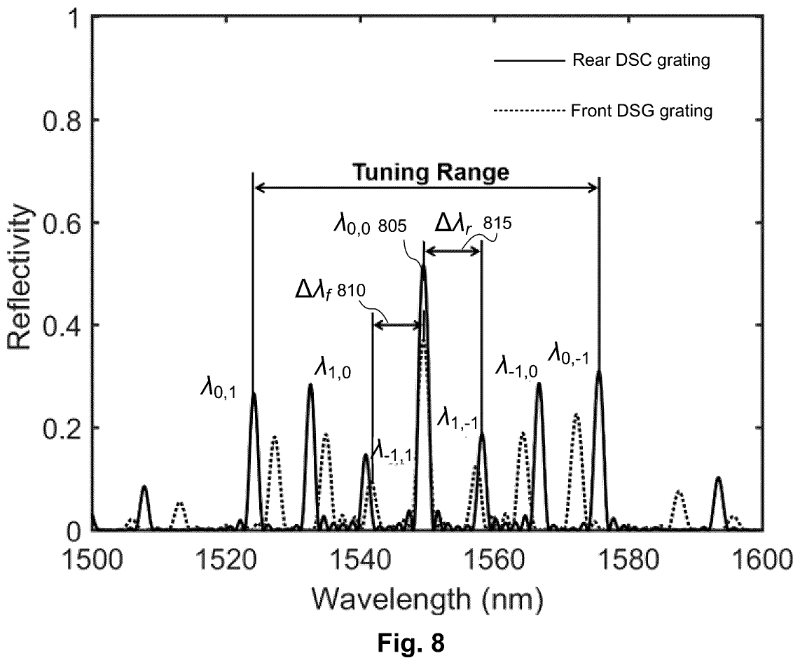

FIG. 8 includes a reflection spectrum for a simulated front DSG 420, and a reflection spectrum for a simulated rear DSG 425, according to an embodiment. The solid line spectrum can be for the rear DSG 425 used as a rear mirror in the laser source 400 shown in FIG. 4, and the dashed line spectrum can be for the front DSG 420 used as a mirror in the laser source 400 shown in FIG. 4. As can be seen, the central wavelength of the front DSG 420 and the central wavelength of the rear DSG 425, can be overlapped at 1549 nm 805. The FSR of the front DSG 420 is Δλ_{f}=7 nm 810, and for the rear DSG 425, it is 42, Δλᵣ=8 nm 815. This is consistent with values obtained with eq. (C). To allow an output of laser light from the front facet of the laser cavity 405, the reflectivity of the front DSG 420 can be less than the reflectivity of the rear DSG 425.

By adjusting external bias currents, external bias voltages, or local temperatures applied to the front and rear grating regions 450, 455, reflection peaks can be shifted such as to make one of the reflection peaks of the front DSG420 overlap with one of the reflection peaks of the rear DSG 425, and optical waves at the corresponding wavelength can resonate as the laser source's wavelength. In an embodiment, the tuning range for the lasing wavelength can be approximated as:

$$Δλ = \vert \frac{Δ {λ}_{f} Δ {λ}_{r}}{Δ {λ}_{f} - Δ {λ}_{r}} \vert = 56 nm$$

A DSG, such as the front DSG 420 or the rear DSG 425, according to an embodiment may not allow all orders of diffraction to be present, and because of this, a tuning range for a lasing wavelength can be limited to 48 nm. This, however, is still greater than in some other embodiments and prior art.

In an embodiment of a laser source 400, the FSR of a DSG, such as the front DSG 420 or the rear DSG 425, can be slightly increased, leading to smaller sampling periods and consequently, a shorter length for the DSG (e.g. the front and rear DSGs 420, 425). As a result, the tuning range of the laser source's 400 laser wavelength can be increased to Δλ=48 nm, and the total grating length can be reduced to 450 μm.

By comparing the reflection spectra shown in FIG. 7 with those of FIG. 8, a trade-off can be noted in that the intensities of the reflection peaks in the latter are reduced. This can result in lasing conditions that include a higher gain and/or a higher lasing threshold current. To cover an increased FSR, the effective refractive indices of front and rear DSGs 420, 425 can require increased tuning. This can be done by applying a greater external bias current, bias voltage, or heat level into the front and/or rear DSGs 420, 425. If the length of a gain region is around 150 μm and the phase tuning region is around 50 μm, the total length of the laser cavity 405 can be reduced to around 650 μm. With the laser cavity 405 having such a length, the laser source 400 can be modulated directly at up to 5 or 6 Gbps.

Therefore, in other words, in the laser source 400 according to embodiments, extending a lasing wavelength tuning range and reducing the lengths of the grating regions and the laser cavity 405, can be compromised by a higher threshold current and greater material refractive index tuning, in both the front and rear grating regions. With a total grating length of 450 μm and a laser cavity length of 650 μm, a lasing wavelength tuning range can achieve 48 nm. It is estimated that a laser with such a cavity length can be directly modulated at 5 to 6 Gbps.

Embodiments include a DSG, which can be used as a mirror of a laser cavity of a wideband tunable laser operating on an effect similar to a Vernier effect. In comparison with a laser cavity using SSGs as mirrors, embodiments using DSGs as mirrors can have a shorter laser cavity.

The reflectivity spectrum of a DSG according to an embodiment, such as the front DSG 420 or the rear DSG 425, can be comb-shaped, thereby enabling a lasing wavelength to be tuned within a wide range, via a Vernier effect. By shortening the DSG pattern's sampling periods, the length of a laser cavity that includes the DSGs as mirrors can be reduced, and this can enable the laser to be directly modulated at high speed (i.e. high frequency).

Embodiments of the present invention include multiple-sampled gratings, such as a triple-sampled grating (TSG), the pattern of which periodically samples a DSG. Embodiments also include a quadruple-sampled grating (QSG), the pattern of which periodically samples a TSG. Further embodiments include further gratings having patterns that periodically sample simpler multiple-sampled gratings. Such variants can be used for applications including an optical wavelength filter, a laser source, a wavelength division multiplexer, a wavelength division demultiplexers, an optical sensor, a mode-locked laser, and more.

Embodiments include a wideband tunable directly modulated laser cavity wherein each one of two mirrors bounding the laser cavity is a DSG, a gain region of the laser cavity is configured to amplify passing optical radiation in a broad range of wavelengths under injection of a current, and a phase tuning region of the laser cavity is configured to match the laser cavity with wavelength reflected by the two mirrors.

In an embodiment of a tunable optical filter, or in an embodiment of a laser source in which a front DSG and a rear DSG have respective reflection spectra, the two reflection spectra can be tuned separately and independently. Furthermore, the front DSG can be partially transparent to a spectrum of optical wavelengths that are useful for applications of a laser source, and a rear DSG can be substantially opaque to those wavelengths.

Embodiments include a dual-sampled grating wideband tunable directly modulated laser cavity, wherein a partially transparent mirror bounding the front cavity and a mirror bounding the rear cavity, are dual-sampled gratings.

Embodiments include a dual-sampled grating wherein the base grating is a Bragg grating with a period Λ₀ and a duty cycle p₀. A first sampling of the grating can have a period Λ₁ and a duty cycle p₁. A second sampling of the grating can be formed with a period Λ₂ that is generally different than period Λ₁, and a duty cycle p₂ that is generally different than duty cycle p₂. A period can be a substantially square period of refractive index such as can be produced with a pair of different materials having high and low refractive indices denoted by n₁ and n₂, respectively. A refractive index can also be sinusoidal, with a crest and trough corresponding to high and low refractive indices denoted by n₁ and n₂, respectively. Embodiments also include periodicity profiles other than sinusoidal and square waves, such as superpositions of multiple sinusoidal waves each one having a different period and amplitude.

Embodiments include a dual-sampled grating having a reflection spectrum with a comb-shaped profile. A central wavelength of a reflection spectrum can be determined by a base Bragg grating. The wavelength spacings between adjacent reflection peaks (FSR) can be determined by both a period of each sampling, namely Λ₁ and Λ₂.

Embodiments include a dual-sampled grating having sufficiently small sampling periods for its length to be shorter than a single-sampled grating having the same FSR, thereby allowing a laser cavity made from two such dual-sampled gratings to be shorter, than a laser cavity made from two single-sampled gratings having the same FSR.

Embodiments include a dual-sampled grating, wherein a first sampling period Λ₁ and a second sampling period Λ₂ are such that for in a section of the dual-sampled grating, the FSR is substantially the same for any two adjacent reflection peaks.

Embodiments include a laser cavity bounded by a front DSG and a rear DSG wherein the FSR (Δλ_{f}) of the front DSG section and the FSR of the rear DSG (Δλᵣ) are different, such as to allow a Vernier effect by which for a range of wavelengths that can be amplified by a gain medium, one reflection peak of the front DSG can coincide with one reflection peak of the rear DSG, and the coincidence can be tuned by tuning the respective refractive indices of the front and rear DSGs.

Embodiments include a laser cavity bounded by a front DSG and a rear DSG, wherein the reflection spectrum of the front DSG can be tuned by changing its refractive indices with a first injected current and the reflection spectrum of the rear grating can also be tuned by changing its refractive indices with second injection current.

Embodiments include a laser cavity bounded by a front DSG and a rear DSG, wherein the reflection spectrum of the front DSG can be tuned by changing its temperature and the reflection spectrum of the rear grating can also be tuned by changing its temperature.

Embodiments include a laser cavity bounded by a front DSG and a rear DSG wherein lasing can occur when a reflection peak of the front DSG coincides with a reflection peak of the rear DSG.

Embodiments include a laser cavity bounded by a front DSG and a rear DSG in which a lasing wavelength can be tuned by changing the refractive index of the front DSG and/or the refractive index of the rear DSG, according to the working principle of the Vernier effect, and the tuning range Δλ can be determined according to the following equation where Δλ_{f} and Δλᵣ are respectively the FSR of the front and back DSGs:

$$Δλ = \vert \frac{Δ {λ}_{f} Δ {λ}_{r}}{Δ {λ}_{f} - Δ {λ}_{r}} \vert$$

Embodiments include a laser cavity with a gain medium bounded by a front DSG and a rear DSG wherein the lasing amplitude can be directly modulated by applying an injection current to the gain medium.

Embodiments include an optical device comprising a grating medium having a periodic refractive index the periodicity of which includes a base period Λ₀, a first period Λ₁, and a second period Λ₂; such that a reflection spectrum of the grating medium includes a plurality of reflection peaks.

In embodiments, the periodic refractive index of a grating medium can further comprise a duty cycle associated with the first period Λ₁, and a duty cycle associated with the second period Λ₂, wherein first period Λ₁ is different from the second period Λ₂.

In embodiments, for a given separation between adjacent reflection peaks, the separation referred to as the reflection spectrum's free spectral range (FSR), the length of the grating medium can be shorter than the length of another grating medium having a single first period.

In embodiment, the FSR of a grating medium can be substantially proportional to the difference between the first period Λ₁ and the second period Λ₂; and inversely proportional to the product between the first period Λ₁ and the second period Λ₂.

In embodiments, the periodic refractive index of a grating medium can further comprise one or more additional periods and one or more additional duty cycles.

In embodiments, a grating medium can include a first material having a first refractive index, and a second material having a second refractive index.

In embodiments, an optical device can further include, interfaced with a first grating medium, a second grating medium having a second periodic refractive index, the periodicity of which has second parameters including: a base period Λ₃′, a first period Λ₁′, a first duty cycle p₁′, a second period Λ₂′, and a second duty cycle p₂′; wherein the second parameters are selected such that a reflection spectrum of the second grating medium includes a plurality of reflection peaks.

In embodiments, the periodic refractive index of at least one grating medium can be operative to be tuned such that a reflection peak of a first grating medium is shifted to coincide with a reflection peak of a second grating medium.

In embodiments, an optical device can include, interfaced between a first grating medium and a second grating medium, a phase tuning medium having a refractive index the tuning of which can cause the phase of optical waves propagated within to be shifted; and a gain medium, the tuning of which can cause the amplitude of optical waves propagated within to be modulated.

In embodiments, tuning of the refractive index of one or more mediums can be performed with current injection.

In embodiments, tuning of the refractive index of one or more mediums can be performed by tuning the medium's temperature.

In embodiments, tuning of the refractive index of one or more mediums can be performed by applying an external electric field to the medium.

In embodiments, tuning of the refractive index of one or more mediums can be performed by applying mechanical force to the medium.

In embodiments, tuning of a gain medium can be performed with current injection.

In embodiments, a medium can be a stack of films, deposited on a substrate, and can further include films to improve electrical connections.

In embodiments, one or more mediums can be electrically doped.

Embodiments include methods of filtering at least one wavelength from an optical beam, comprising: applying to a base grating medium having a periodic refractive index the period of which is Λ₀, a first period Λ₁ and a second period Λ₂; such that a reflection spectrum of the resulting grating includes a plurality of reflection peaks.

In embodiments, a method can further include a periodic refractive index having a duty cycle associated with the first period Λ₁, and a duty cycle associated with the second period Λ₂, wherein first period Λ₁ is different from the second period Λ₂.

In embodiments, for a given separation between adjacent reflection peaks, the separation referred to as the reflection spectrum's free spectral range (FSR), the length of the grating medium can be made shorter than the length of another grating medium having a single first period.

In embodiments the FSR between adjacent reflection peaks of a grating medium having a periodic refractive index can be substantially proportional to the difference between the first period Λ₁ and the second period Λ₂; and inversely proportional to the product between the first period Λ₁ and the second period Λ₂.

In embodiments, a method of filtering at least one wavelength can include a grating medium having one or more additional periods and one or more additional duty cycles.

In embodiments, a method can include the grating medium having a first material having a first refractive index, and a second material having a second refractive index.

In embodiments, a method can further include interfacing to a first grating medium, a second grating medium having a second periodic refractive index, the periodicity of which has second parameters including: a base period Λ₀′, a first period Λ₁′, a first duty cycle p₁′, a second period Λ₂′, and a second duty cycle p₂′; wherein the second parameters are selected such that a reflection spectrum of the second grating medium includes a plurality of reflection peaks.

In embodiments, a method can further include tuning the periodic refractive index of at least one grating medium such that one reflection peak of the first grating medium is shifted to coincide with one reflection peak of the second grating medium.

In embodiments, a method can further include interfacing between a first grating medium and a second grating medium, a phase tuning medium having a refractive index the tuning of which causes the phase of optical waves propagated within to be shifted; and a gain medium, the tuning of which causes the amplitude of optical waves propagated within to be modulated.

In embodiments, tuning the refractive index of one or more mediums can be performed with current injection.

In embodiments, tuning the refractive index of one or more mediums can be performed by tuning the medium's temperature.

In embodiments, tuning the refractive index of one or more mediums can be performed by applying an external electric field to the medium.

In embodiments, tuning the refractive index of one or more mediums can be performed by applying mechanical force to the medium.

In embodiments, tuning a gain medium can be performed by current injection.

Embodiments have been described above in conjunction with aspects of the present invention upon which they can be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

Although the present invention has been described with reference to specific features and embodiments thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A dual-sampled grating (DSG) comprising:
a medium having a periodic refractive index, wherein overall periodicity of the medium results from:
a base periodicity having
a base period Λ₀ and
a base duty cycle p₀,
a first periodicity that samples the base periodicity with
a first period Λ₁ and
a first duty cycle p₁, and
a second periodicity that samples the first periodicity with
a second period Λ₂ and
a second duty cycle p₂;
wherein a reflection spectrum of the dual-sampled grating includes a plurality of reflection peaks.

2. The dual-sampled grating of claim 1 wherein the second period Λ₂ is different from the first period Λ₁.

3. The dual-sampled grating of claim 1, wherein the medium having the periodic refractive index comprises two different materials respectively having two different refractive indices.

4. The dual-sampled grating of claim 1, wherein the medium having the periodic refractive index comprises one base material, wherein refractive index of the one base material varies periodically and gradually along a length of the medium.

5. A method comprising:
inscribing, with an electron beam or an ultraviolet beam,
on a photoresist covering a first material having a first refractive index,
a pattern that results from:
a base periodicity having
a base period Λ₀ and
a base duty cycle p₀,
a first periodicity that samples the base periodicity with
a first period Λ₁ and
a first duty cycle p₁, and
a second periodicity that samples the first periodicity with
a second period Λ₂ and
a second duty cycle p₂;
developing the photoresist;
etching
the inscribed pattern of the photoresist, and
the first material having the first refractive index that is underneath the inscribed pattern of the photoresist; and
depositing, in cavities left by the etching, a second material having a second refractive index.

6. The method of claim 1 wherein the second period Λ₂ is different from the first period Λ₁.

7. A laser source comprising a laser cavity including:
a first dual-sampled grating (DSG) comprising:
a first grating medium having a first periodic refractive index, wherein overall periodicity of the first grating medium results from:
a base periodicity having
a base period Λ₀ and
a base duty cycle p₀,
a first periodicity that samples the base periodicity with
a first period Λ₁ and
a first duty cycle p₁, and
a second periodicity that samples the first periodicity with
a second period Λ₂ and
a second duty cycle p₂;
a gain medium, interfaced with the first dual-sampled grating;
a phase-tuning medium, interfaced with the gain medium; and
a second dual-sampled grating (DSG) comprising:
a second grating medium having a second periodic refractive index, wherein overall periodicity of the second grating medium results from:
a second base periodicity having
a second base period Λ₀′ and
a second base duty cycle p₀′,
a third periodicity that samples the second base periodicity with
a third period Λ₁′ and
a third duty cycle p₁′, and
a fourth periodicity that samples the third periodicity with
a fourth period Λ₂′ and
a fourth duty cycle p₂′;
wherein
reflection spectrum of each DSG includes a plurality of reflection peaks, and
the first DSG is partially transparent to a spectrum of optical wavelengths for which it is an output.

8. The laser source of claim 7, wherein at least one of the first medium and the second medium further includes at least one electrical contact area allowing an electrical input to tune the at least one of the first medium and the second medium.

9. The laser source of claim 7, wherein at least one of the first medium and the second medium further includes at least one heating pad operative to be tuned with an electrical signal.

10. The laser source of claim 7, further including at least one power supply.

11. The laser source of claim 7, wherein
the first base period Λ₀ is the same as the second base period Λ₀′;
the first period Λ₁ is different from the second period Λ₂;
the third period Λ₁′ is different from the fourth period Λ₂′;
the first period Λ₁ is different from the third period Λ₁′; and
the second period Λ₂ is different from the fourth period Λ₂′.
